(19) United States
(12) Patent Application Publication
(10) Pub. No.: US 2026/0359245 A1
(43) Pub. Date: Nov. 12, 2026

(54) Motherboards Management System, Method, Device, Medium, and Computer Program Product

(71) Applicant: IEIT SYSTEMS CO., LTD., Jinan (CN)

(72) Inventors: Xin XU, Jinan (CN); Zhiyuan SU, Jinan (CN); Guozhen XU, Jinan (CN); Zhichong DOU, Jinan (CN); Chunxing DAI, Jinan (CN); Rongfei XU, Jinan (CN); Fuqiang MA, Jinan (CN)

(73) Assignee: IEIT SYSTEMS CO., LTD., Jinan (CN)

(21) Appl. No.: 19/674,983

(22) Filed: May 12, 2026

(30) Foreign Application Priority Data
May 12, 2025 (CN) 202510607093.2

(51) Int. Cl. G06F 13/40; H05K 1/14

(52) U.S. Cl. CPC G06F 13/4022; H05K 1/14

(57) ABSTRACT

Provided are a system and a method for managing motherboards, device, medium, and computer program product, relating to the field of computer technology. The system includes a controller and a plurality of motherboards, wherein the controller is respectively connected to the plurality of motherboards and one or more functional devices; the controller receives a device link switching instruction and transmits a device removal signal to a first motherboard; the first motherboard controls a host on the first motherboard to suspend an application or a service, which uses the functional device; the controller disconnects the connection between the functional device and the first motherboard, establishes a connection between the functional device and a second motherboard, and transmits a device insertion signal to the second motherboard; the second motherboard resumes an application or a service, which uses the functional device and runs in a host on the second motherboard.

### CROSS-REFERENCE TO RELATED APPLICATION

This application claims priority to Chinese Patent Application No. 202510607093.2, filed to the China National Intellectual Property Administration on May. 12, 2025 and entitled “Motherboard Management System, Method, Device, Medium, and Computer Program Product”, the disclosure of which is hereby incorporated by reference in its entirety.

### TECHNICAL FIELD

The present disclosure relates to the field of computer technology, and in particular, to a motherboards management system, method, device, medium, and computer program product.

### BACKGROUND

A Baseboard Management Controller (BMC), as an embedded controller independent of an operating system, is configured to manage and monitor a motherboard. In related technologies, each of the motherboards needs to be equipped with a corresponding controller to realize monitoring of the hardware status of each of the motherboards and provide functional devices for each of the motherboards, that is, a single controller corresponds to a single motherboard. However, the motherboard does not need to use the functional devices provided by the controller at all times, and the controller does not need to monitor the motherboard in real time. Managing a single motherboard through a single controller leads to resource waste.

Therefore, how to reduce resource waste of the controller managing the motherboard is a technical problem to be solved by those skilled in the art.

### SUMMARY

The present disclosure provides a system and a method for managing motherboards, device, medium, and computer program product, reducing resource waste of the controller managing the motherboards.

The present disclosure provides a system for managing motherboards, the system including a controller and a plurality of motherboards, where the controller is respectively connected to the plurality of motherboards and one or more functional devices.

The controller is configured to: in a case where a functional device among the one or more functional devices is connected to a first motherboard among the plurality of motherboards, receive a device link switching instruction and transmit a device removal signal to the first motherboard; wherein the device link switching instruction indicates to switch a connection of the functional device from the first motherboard to a second motherboard among the plurality of motherboards.

The first motherboard is configured to: in a case where the first motherboard receives the device removal signal, control a host on the first motherboard to suspend an application or a service, which uses the functional device and runs in the host.

The controller is further configured to: after the host on the first motherboard suspends the application or the service, which uses the functional device, disconnect the connection between the functional device and the first motherboard, establish a connection between the functional device and the second motherboard, and transmit a device insertion signal to the second motherboard.

The second motherboard is configured to: in a case where the second motherboard receives the device insertion signal, resume an application or a service, which uses the functional device and runs in a host on the second motherboard.

The present disclosure further provides a method for managing motherboards, the method applied to a controller, wherein the controller is respectively connected to a plurality of motherboards and one or more functional devices, the method including the following operations:
in a case where a functional device among the one or more functional devices is connected to a first motherboard among the plurality of motherboards, transmitting device removal signal to the first motherboard when the controller receives a device link switching instruction, so that a host on the first motherboard suspends an application or a service, which uses the functional device to stop and runs in the host, wherein the device link switching instruction indicates to switch a connection of the functional device from the first motherboard to a second motherboard among the plurality of motherboards.
after the host on the first motherboard suspends the application or the service, which uses the functional device, disconnecting the connection between the functional device and the first motherboard and establishing a connection between the functional device and the second motherboard; and
transmitting a device insertion signal to the second motherboard, so that a host on the second motherboard resumes an application or a service, which uses the functional device and runs in a host on the second motherboard.

The present disclosure further provides a method for managing motherboards, the method applied to a motherboard among a plurality of motherboards in a motherboard management system, wherein a controller in the motherboard management system is respectively connected to a plurality of motherboards and one or more functional devices, the method including the following operations:
in a case where the motherboard receives a device removal signal transmitted by the controller, controlling a host on the motherboard to suspend an application or a service, which uses a functional device among the one or more functional devices connected to the motherboard; and
in a case where the motherboard receives a device insertion signal transmitted by the controller, resuming the application or the service, which uses the functional device.

The present disclosure further provides an electronic device, including: a memory configured to store a computer program; and a processor configured to execute steps of any one of the above methods for managing motherboards when executing the computer program.

The present disclosure further provides a computer-readable storage medium, and a computer program is stored in the computer-readable storage medium, where the computer program, when executed by a processor, implements steps of any one of the above methods for managing motherboards.

The present disclosure further provides a computer program product, including a computer program, where the computer program, when executed by a processor, implements steps of any one of the above motherboard management methods.

The present disclosure realizes managing a plurality of motherboards by a single controller, reducing resource waste of the controller managing the motherboards. Meanwhile, the present disclosure realizes hot switching of a functional device between different motherboards through collaborative work between the controller and the plurality of motherboards. After the controller receives a device link switching instruction, the controller transmits a device removal signal to a first motherboard among the plurality of motherboards. After the first motherboard receives the device removal signal, a host on the first motherboard can timely suspend an application or a service, which uses the functional device and runs in the host, avoiding data loss or application crash caused by sudden disconnection of the functional device. Only after confirming that the host on the first motherboard has stopped using the functional device, the controller disconnects the connection with the first motherboard, establishes a connection with a second motherboard among the plurality of motherboards, and simultaneously transmits a device insertion signal to the second motherboard, enabling a host on the second motherboard to resume an application or a service. This mechanism ensures a smooth transition of a device link switching process, avoids impact on host services due to device link switching, and improves reliability and stability of host services.

The present disclosure further discloses a method for managing motherboards, an electronic device, a computer-readable storage medium, and a computer program product which can also achieve the above technical effects.

It should be understood that the above general description and the following detailed description are merely exemplary and do not limit the present disclosure.

### BRIEF DESCRIPTION OF THE DRAWINGS

To illustrate the embodiments of the present disclosure more clearly, a brief description will be given below to the drawings required in the embodiments. It is apparent that the drawings described below are merely some embodiments of the present disclosure. For those of ordinary skill in the art, other drawings may also be obtained based on these drawings without exercising creative labor.

FIG. 1 is a structural diagram of a system for managing motherboards according to an exemplary embodiment.

FIG. 2 is a routing state transition diagram according to an exemplary embodiment.

FIG. 3 is a structural diagram of a system for managing motherboards in an application embodiment provided by the present disclosure.

FIG. 4 is a timing diagram of a controller switching a device link in an application embodiment provided by the present disclosure.

FIG. 5 is a timing diagram of functional device removal in an application embodiment provided by the present disclosure.

FIG. 6 is a timing diagram of functional device insertion in an application embodiment provided by the present disclosure.

FIG. 7 is a timing diagram of a motherboard application requesting to switch a device link in an application embodiment provided by the present disclosure.

FIG. 8 is a flowchart of a method for managing motherboards according to an exemplary embodiment.

FIG. 9 is a flowchart of another method for managing motherboards according to an exemplary embodiment.

FIG. 10 is a structural diagram of an electronic device according to an exemplary embodiment.

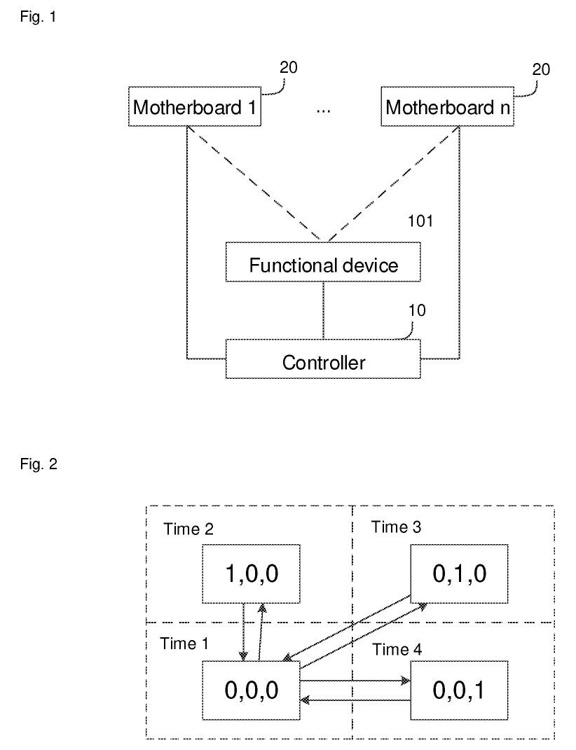

### DETAILED DESCRIPTION OF THE EMBODIMENTS

The technical solutions in the embodiments of the present disclosure will be described clearly and completely below in conjunction with the drawings in the embodiments of the present disclosure. It is apparent that the described embodiments are merely some, rather than all, embodiments of the present disclosure. Based on the embodiments in the present disclosure, all other embodiments obtained by those of ordinary skill in the art without making creative efforts shall fall within the protection scope of the present disclosure.

It should be noted that in the description of the present disclosure, terms such as "include", "contain" or any other variants thereof are intended to cover non-exclusive inclusion, so that a process, method, article, or device including a series of elements includes not only those elements but also other elements not explicitly listed, or further includes elements inherent to such process, method, article, or device. Terms such as "first", "second", etc. in the present disclosure are used for distinguishing similar objects and are not used for describing a specific order or sequence.

To enable those skilled in the art to better understand the solution of the present disclosure, detailed description of the present disclosure is further provided below in conjunction with the drawings and specific implementations.

This embodiment provides a system for managing motherboards, the system including a controller 10 and a plurality of motherboards 20, wherein the controller 10 is respectively connected to the plurality of motherboards 20 and one or more functional devices 101.

The controller 10 is configured to: in a case where a functional device among the one or more functional devices 101 is connected to a first motherboard among the plurality of motherboards, receive a device link switching instruction and transmit a device removal signal to the first motherboard, wherein the device link switching instruction indicates to switch a connection of the functional device 101 from the first motherboard to a second motherboard among the plurality of motherboards.

The first motherboard is configured to: in a case where the first motherboard receives the device removal signal, control a host on the first motherboard to suspend an application or a service, which uses the functional device 101 and runs in the host.

The controller 10 is further configured to: after the host on the first motherboard suspend the application or the service, which uses the functional device 101, disconnect the connection between the functional device 101 and the first motherboard, establish a connection between the functional device 101 and the second motherboard, and transmit a device insertion signal to the second motherboard.

The second motherboard is configured to: in a case where the second motherboard receives the device insertion signal, resume an application or a service, which uses the functional device 101 and runs in a host on the second motherboard.

The controller 10 in this embodiment is a control device independent of the plurality of motherboards, which may be a BMC. The controller 10 is configured to monitor a plurality of hosts running on the plurality of motherboards and provide the functional devices for the plurality of hosts, such as Video Graphic Array (VGA), Universal Serial Bus (USB), etc.

In an initial state, the functional device 101 is connected to the first motherboard, and configured to support the relevant applications and services of a host running on the first motherboard. In a case where the functional device 101 needs to be switched from the first motherboard to the second motherboard, the controller 10 receives a device link switching instruction, wherein the device link switching instruction explicitly indicates that the connection target of the functional device 101 switches from the first motherboard to the second motherboard. The controller 10 transmits the device removal signal to the first motherboard according to the device link switching instruction, notifying the first motherboard to prepare to release the functional device 101.

After the first motherboard receives the device removal signal, the first motherboard executes a series of operations to ensure a smooth transition. Specifically, control a host running on the first motherboard suspends all of the applications or services internally, which use the functional device 101 and run in the host, avoiding data loss or system instability caused by continuous operation of applications during device switching. After completing the suspending of the applications and services, the controller 10 detects that the host running on the first motherboard has properly handled the release work of the functional device 101, and subsequently disconnects the connection between the functional device 101 and the first motherboard.

After disconnecting the connection with the first motherboard, the controller 10 immediately establishes a connection between the functional device 101 and the second motherboard, ensuring that the functional device 101 can seamlessly switch to a new motherboard. After the connection is established, the controller 10 transmits the device insertion signal to the second motherboard, notifying the second motherboard that the functional device 101 is ready, and the host running on the second motherboard can resume the use of the relevant applications and services, which use the functional device and run in a host on the second motherboard. After the second motherboard receives the device insertion signal, the host running on the second motherboard resumes the applications or services previously suspended due to device switching, enabling the functional device 101 to normally provide services for the host running on the second motherboard, thereby realizing hot switching of the functional device 101 between different hosts and guaranteeing continuity and stability of host services.

Embodiments of the present disclosure realize managing a plurality of motherboards by a single controller, reducing resource waste of the controller managing the motherboards. Meanwhile, the embodiments of the present disclosure realize hot switching of a functional device between different motherboards through collaborative work between the controller and the plurality of motherboards. After the controller receives a device link switching instruction, the controller transmits a device removal signal to a first motherboard among the plurality of motherboards. After the first motherboard receives the device removal signal, a host on the first motherboard can timely suspend an application or a service, which uses the functional device and runs in the host, avoiding data loss or application crash caused by sudden disconnection of the functional device. Only after confirming that the host on the first motherboard has stopped using the functional device, the controller disconnects the connection with the first motherboard, establishes a connection with a second motherboard among the plurality of motherboards, and simultaneously transmits a device insertion signal to the second motherboard, enabling a host on the second motherboard to resume an applications or a services. This mechanism ensures a smooth transition of a device link switching process, avoids impact on host services due to device link switching, and improves reliability and stability of host services.

Based on the above embodiment, as a feasible implementation, the controller is connected to a plurality of multiplexers, each multiplexer among the plurality of multiplexers is respectively connected to the plurality of motherboards and a corresponding type functional device among the one or more functional devices, and each multiplexer among the plurality of multiplexers is configured to control establishment or disconnection of a connection between the corresponding type functional device and the plurality of motherboards.

In specific implementation, the controller manages connections between the functional device and the motherboards through the plurality of multiplexers. This design allows the controller to flexibly switch links between the functional device and different motherboards. Specifically, each type of the functional device is equipped with an independent multiplexer controller configured to control the connection status of the functional device with various motherboards. When the functional device needs to be switched from one motherboard to another, the controller completes link establishment and disconnection operations through the corresponding multiplexer controller.

As shown in FIG. 2, taking the controller managing three motherboards as an example, state 0 represents link disconnection; state 1 represents link establishment; [0,0,0] state represents [motherboard 1 disconnected, motherboard 2 disconnected, motherboard 3 disconnected], and this state generally appears after the device removal operation is completed and immediately before the device insertion operation is executed; and [0,1,0] state represents [motherboard 1 disconnected, motherboard 2 connected, motherboard 3 disconnected], and this state indicates that motherboard 2 establishes a device link with the functional device. Multiplexer connection state switching follows the principle of finite states, i.e., states are finite (at most one motherboard maintains a device link with the functional device) and transition directions are finite (a device link with a new motherboard can only be established after disconnecting the device link with the original motherboard).

This mechanism not only improves flexibility of resource management but also ensures that the functional device can only establish a connection with one motherboard at the same time, thereby avoiding potential conflicts and resource waste.

Based on the above embodiment, as a feasible implementation, the controller includes a management module, a monitoring switching module, and a routing control module; the management module is configured to: receive the device link switching instruction and transmit the device link switching instruction to the monitoring switching module; the monitoring switching module is configured to: transmit the device removal signal to the first motherboard in a case where the monitoring switching module receives the device link switching instruction, and transmit a device link switching request to the routing control module after the host running on the first motherboard suspends the application or the service which uses the corresponding type functional device; the routing control module is configured to: in a case where the routing control module receives the device link switching request, control the multiplexer to disconnect a connection with the first motherboard and control the multiplexer to establish a connection with the second motherboard; and the monitoring switching module is further configured to: transmit the device insertion signal to the second motherboard after the multiplexer establishes the connection with the second motherboard.

In specific implementation, the controller includes a management module, a monitoring switching module, and a routing control module. This modular design enables the controller to efficiently process the device link switching instructions and coordinate connections between the plurality of motherboards and the functional device.

The management module is an interface for interaction between the controller and the outside, responsible for receiving the device link switching instruction from the outside. The device link switching instruction may be issued by a system administrator through an interface (such as a Web interface). After the management module receives the instruction, the management module converts the device link switching instruction into an internally processable format and transmits the device link switching instruction to the monitoring switching module to ensure correct execution of the device link switching instruction.

The monitoring switching module undertakes key coordination tasks. In a case where the monitoring switching module receives the device link switching instruction forwarded by the management module, the monitoring switching module first transmits the device removal signal to the first motherboard currently connected to the functional device. The function of this signal is to notify the host running on the first motherboard to suspend using the functional device. After the host running on the first motherboard completes the suspending operation of the relevant applications or services, which use the functional device, the monitoring switching module transmits a device link switching request to the routing control module, triggering the actual switching process of the link. After the routing control module completes the link switching, successfully disconnecting the functional device from the first motherboard and connecting the functional device to the second motherboard, the monitoring switching module then transmits a device insertion signal to the second motherboard, informing a host running on the second motherboard that the functional device is ready and can be used.

The routing control module is responsible for specific link switching operations. In a case where the routing control module receives the device link switching request transmitted by the monitoring switching module, the routing control module transmits an instruction to the multiplexer controller to control a selector of the multiplexer to complete the link switching. The multiplexer controller disconnects the connection between the functional device and the first motherboard and establishes a connection with the second motherboard according to the instruction. The routing control module ensures that all of the functional devices establish a link with only one motherboard at the same time by precisely controlling the multiplexer, avoiding potential conflicts and resource allocation errors.

Through this modular design, the controller can clearly divide responsibilities of different functional modules, making a device link switching process more efficient and orderly. The management module is responsible for receiving and forwarding the instructions, the monitoring switching module is responsible for coordinating the operations between the motherboards and the functional devices, and the routing control module focuses on actual link switching. This division of labor and collaboration not only improves system reliability but also facilitates subsequent maintenance and upgrades.

As a preferred implementation, the controller further includes a log recording module and an exception handling module; the log recording module is configured to: record an operation log during the device link switching process, wherein the operation log includes any one or any combination of a reception time of the device removal signal, a transmission time of the device insertion signal, and a switching action of the multiplexer; and the exception handling module is configured to: in a case where the exception handling module detects an exception condition during the device link switching process, execute an exception handling strategy corresponding to the exception condition.

In specific implementation, the controller is not only responsible for managing link switching between the functional device and the plurality of motherboards but also integrates log recording and exception handling functions to enhance system reliability and maintainability. The function of the log recording module is to record key operations in detail during the device link switching process, such as the reception time of the device removal signal, the transmission time of the device insertion signal, and specific actions of the multiplexer during the switching process. These log information are crucial for tracking operation history, analyzing system performance, and diagnosing problems. Meanwhile, in a case where the exception handling module detects any exception condition during the link switching process, the exception handling module immediately executes a preset exception handling strategy, which may include error recovery, automatic retry, or notifying an administrator, to ensure the system can quickly recover from the exceptions and guarantee continuity and stability of functional device switching. Through collaborative work of these two modules, the system can more intelligently and automatically handle various situations that may occur during device link switching.

Based on the above embodiment, as a feasible implementation, an operating system of the host running on a motherboard among the plurality of motherboards includes a kernel state and a user state, the kernel state includes a removal signal monitoring module and an insertion signal monitoring module, and the user state includes a device unloading module and a device probing module; the removal signal monitoring module is configured to: monitor a device removal signal, and in a case where the removal signal monitoring module monitors the device removal signal, transmit the device removal signal to the device unloading module; the device unloading module is configured to: in a case where the device unloading module receives the device removal signal, suspend an application or a service, which uses the functional device and runs in the host on the motherboard among the plurality of motherboards; the insertion signal monitoring module is configured to: monitor a device insertion signal, and in a case where the insertion signal monitoring module detects the device insertion signal, transmit the device insertion signal to the device probing module; and the device probing module is configured to: in a case where the device probing module receives the device insertion signal, resume the application or the service, which uses the functional device and runs in the host on the motherboard among the plurality of motherboards.

In specific implementation, the operating system of the host is divided into kernel state modules and user state modules. This modular design enables the host to efficiently respond to the device removal and insertion signals and coordinate suspending and resuming of applications and services.

In the kernel state of the operating system, the removal signal monitoring module is responsible for monitoring the device removal signals in the signal link. After receiving the device removal signal, the removal signal monitoring module forwards the signal to the device unloading module in the user state, triggering application stopping and device unloading operations. This process ensures that the current host can safely release the functional device before device switching, avoiding data loss or application anomalies during device switching. The insertion signal monitoring module is responsible for monitoring the device insertion signals in the signal link. After receiving the device insertion signal, the insertion signal monitoring module forwards the signal to the device probing module in the user state, triggering device loading and application resuming operations. This process ensures that the new host can quickly resume use of the functional device after device switching is completed, guaranteeing business continuity.

In the user state of the operating system, the device unloading module receives a request from the removal signal monitoring module in the kernel state and suspends the application or the service, which uses the functional device, avoiding data loss or system instability caused by continuous operation of the applications during device switching. The device probing module receives a request from the insertion signal monitoring module in the kernel state and resumes the applications or services previously suspended due to device removal. This process ensures that the new host can quickly resume use of the functional device after device switching is completed.

Through this modular design of the kernel state and the user state, the host can clearly divide responsibilities of different modules, making the device switching process more efficient and orderly. The kernel state modules are responsible for monitoring signals and coordinating operations of the user state modules, while the user state modules are responsible for specific operations such as application stopping, device unloading, device loading, and application resuming. This division of labor and collaboration not only improves system reliability but also facilitates subsequent maintenance and upgrades.

Based on the above embodiment, as a feasible implementation, the device unloading module is specifically configured to: in a case where the device unloading module receives the device removal signal, suspend or save the application or the service, which uses the functional device and runs in the host on the motherboard among the plurality of motherboards, remove the functional device from a maintained managed device set, and unload a driver of the functional device; and the device probing module is specifically configured to: add the functional device to the maintained managed device set, load the driver of the functional device, and resume the application or the service, which uses the functional device and runs in the host on the motherboard among the plurality of motherboards.

In specific implementation, the device unloading module is mainly responsible for ensuring that a current motherboard safely releases the functional device before device switching, while the device probing module is responsible for quickly resuming use of the functional device after device switching.

In a case where the device unloading module receives the device removal signal, the device unloading module first suspends or saves the application or service currently using the functional device. This is to ensure that these applications or services do not encounter anomalies or data loss due to sudden removal of the functional device during device switching. For example, if a certain application is transmitting data through the functional device, the device unloading module suspends the data transmission operation of the application to ensure data integrity. Then, the functional device is removed from the maintained managed device set of the system. This means the system no longer regards the functional device as an available device, thereby preventing other applications or services from mistakenly operating the device. Furthermore, the driver of the functional device is unloaded. The driver is a bridge for communication between the operating system and the hardware device. Unloading the driver ensures that the device is not mistakenly operated by the system during switching and also prepares for reloading the device on a new motherboard.

In a case where the device probing module receives the device insertion signal, the device probing module first adds the functional device back to the maintained managed device set of the system. This means the system re-identifies the functional device and regards it as an available device. Then, the driver of the functional device is loaded according to the type and specification of the functional device, ensuring that the operating system can communicate with the functional device and enabling the functional device to work normally.

It can be seen that through specific function implementation of the device unloading module and the device probing module, the motherboard can safely and efficiently release and resume the functional device during functional device switching. The device unloading module ensures the functional device is correctly suspended and removed before switching, avoiding anomalies during device switching; and the device probing module ensures the functional device can quickly resume use after switching, guaranteeing business continuity. This mechanism not only improves system reliability but also optimizes efficiency of device switching, ensuring efficient operation of the motherboard in a multi-functional devices environment.

Based on the above embodiment, as a feasible implementation, after the device unloading module suspends or saves the application or the service, which uses the functional device and runs in the host on the motherboard among the plurality of motherboards, the device unloading module is further configured to: set a power state of the functional device to a low-power state; and after the device probing module loads the driver of the functional device, the device probing module is further configured to: set the power state of the functional device to a working state. The controller is specifically configured to: in a case where the controller detects that the power state of the functional device is the low-power state, disconnect the connection between the functional device and the first motherboard, and establish the connection between the functional device and the second motherboard.

In specific implementation, after completing the suspending or saving operation of the application or service using the functional device, the device unloading module sets the power state of the functional device to the low-power state. This low-power mode is an energy-saving state where the functional device retains only necessary functions to reduce energy consumption while ensuring rapid response to wake-up signals. By detecting the power state of the functional device, the controller confirms that the device has entered the low-power state, then disconnects the connection between the functional device and the first motherboard and establishes the connection with the second motherboard. This process ensures the functional device is not accidentally used during switching, avoiding potential conflicts and data loss.

After completing loading of the functional device driver, the device probing module switches the power state of the functional device to the working state. The working state is the normal operation mode of the functional device, wherein the functional device can execute all functions in this state. The device probing module restores all functions of the functional device by controlling a power management module of the functional device, enabling the functional device to work normally. After the device power state switches to the working state, the device probing module resumes the applications or services previously suspended due to the functional device removal, allowing these applications or services to immediately start using the functional device, thereby ensuring business continuity.

Through this power state management mechanism, the motherboard system can realize low power consumption and fast recovery during functional device switching. The device unloading module ensures the functional device enters the low-power state after removal, reducing energy consumption and guaranteeing the functional device is in a safe state; and the device probing module switches the functional device to the working state after reloading, quickly restoring device functions of the functional device. The controller ensures safety and reliability of the functional device during switching by detecting the power state of the functional device. This mechanism not only improves system energy efficiency but also optimizes efficiency of device switching, ensuring efficient operation of the motherboard in a multi-functional devices environment.

Based on the above embodiment, as a preferred implementation, the kernel state further includes a link request module, and the user state further includes a device application module; the device application module is configured to: determine whether a connection exists between the functional device and a motherboard where the device application module is located before the application or the service uses the functional device, and in a case where a connection does not exist between the functional device and the motherboard where the device application module is located, transmit a link request signal to the link request module; the link request module is configured to: transmit the link request signal to the controller in a case where the link request module receives the link request signal; and the controller is configured to: trigger device link switching in a case where the controller receives the link request signal.

In specific implementation, the link request module is added to the kernel state of the motherboard, and the device application module is added to the user state. The function of the device application module is to first check whether a connection has been established between the functional device and the current motherboard before the application or service needs to use the functional device. If it is detected that the functional device is not yet connected to the current motherboard, the device application module transmits the link request signal to the link request module. After receiving the link request signal, the link request module forwards it to the controller. Upon receiving the link request signal, the controller triggers a device link switching process to establish a connection between the functional device and the current motherboard.

To implement this link switching mechanism, each of the motherboards needs to establish two non-device communication links with the controller. One link is configured to receive the device insertion or removal signals initiated by the controller, and the other link is configured for the motherboard to initiate a link request to the controller. These links may use common signal links, such as GPIO or I2C signal links. Through this design, the motherboard can actively request to establish a connection with the functional device when needed, thereby improving flexibility and efficiency of the system.

It can be seen that in this embodiment, the host running on the motherboard can actively trigger link switching when needing to use the functional device without waiting for external instructions, thereby improving flexibility and response speed of the system.

Based on the above embodiment, as a feasible implementation, the functional device includes any one or any combination of a storage device, a network device, and a graphics processing device; the controller is further configured to: generate an instruction for adjusting a resource allocation strategy of the functional device according to a type and a current connection state of the functional device; and the motherboard further includes a resource management module, which configured to allocate and adjust resources of the functional device according to the instruction of the controller.

In specific implementation, the controller generates corresponding instructions to adjust the resource allocation strategies according to the type and the current connection state of the functional device, optimizing resource usage, improving system efficiency, and ensuring the functional device obtains appropriate resource support according to actual workloads and performance requirements. Meanwhile, the resource management module is integrated on the motherboard, responsible for executing the instructions issued by the controller to specifically allocate and adjust resources of the functional device. The resource management module can dynamically allocate resources such as CPU, memory, and I/O bandwidth for different functional devices to meet system operation requirements.

Through this method, the system can realize refined management of the functional device, improve resource utilization efficiency, and provide greater flexibility and control capabilities for system administrators to adapt to changing workloads and business requirements.

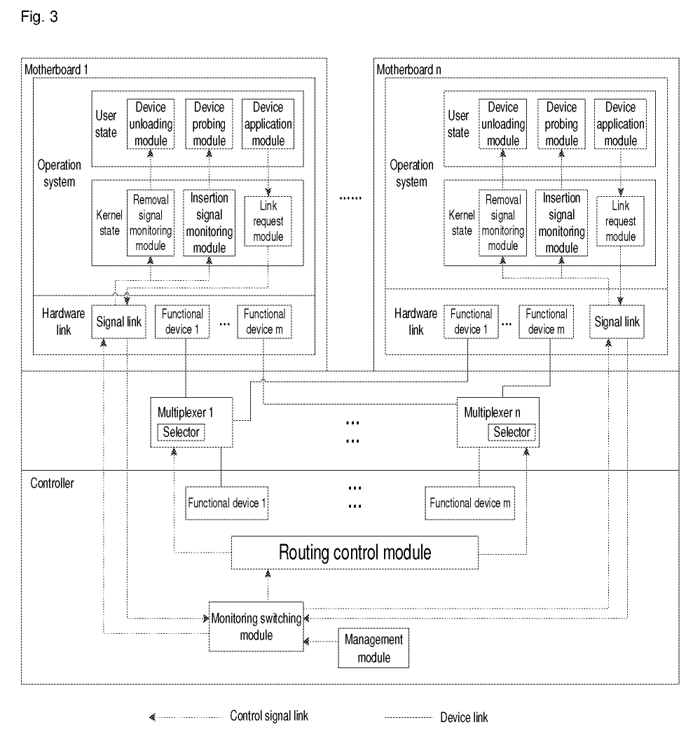

An application embodiment provided by the present disclosure is introduced below. The structural diagram of the system for managing motherboards provided in this embodiment is shown in FIG. 3. The controller includes a management module, a monitoring switching module, and a routing control module. The motherboard includes a kernel state and a user state. The kernel state includes a removal signal monitoring module, an insertion signal monitoring module, and a link request module. The user state includes a device unloading module, a device probing module, and a device application module.

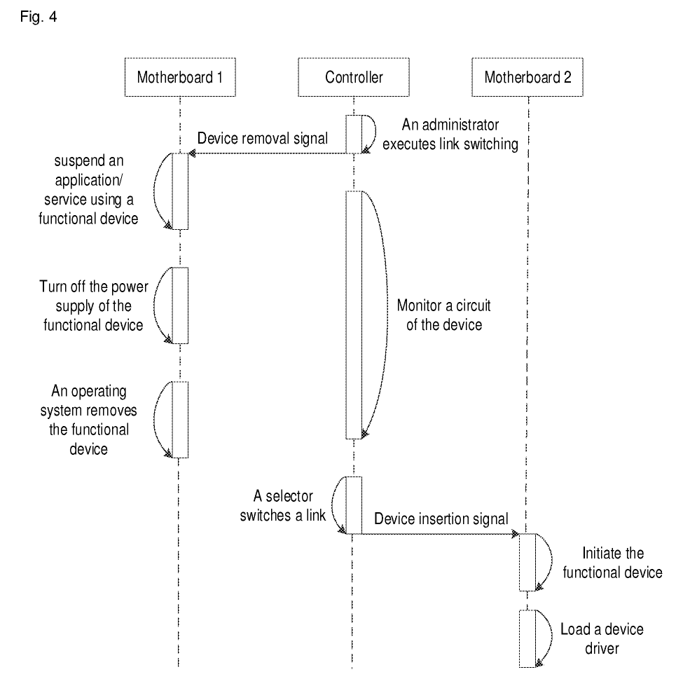

The timing diagram of the controller switching the device link is shown in FIG. 4. A controller administrator initiates a path switching request to the monitoring switching module through a management interface of the controller (e.g., an added menu or button) or through an added command. The path switching request contains information of the original motherboard and a new motherboard, with the purpose of instructing the controller to switch the connection of the functional device from the original motherboard to the new motherboard. After receiving the path switching request, the monitoring switching module transmits a device removal signal to the original motherboard. After receiving the device removal signal, the original motherboard starts executing a device removal process, including suspending or saving applications or services using the functional device, setting the power state of the functional device to a low-power mode, and turning off all device functions. The controller detects the power state of the functional device in real time. When detecting that the power state of the functional device is set to the low-power mode, the controller confirms that the original motherboard has completed management removal of the functional device. After confirming that the original motherboard has removed management of the functional device, the controller transmits a link switching request to a multiplexer connected to the functional device through the routing control module, disconnecting the link between the functional device and the original motherboard, and establishing the link between the functional device and the new motherboard. After the link between the functional device and the new motherboard is established, the monitoring switching module transmits a device insertion signal to the new motherboard. After receiving the device insertion signal, the new motherboard probes and loads the functional device, loads a device driver, completes device initialization operations, enabling the new motherboard to normally use the functional device.

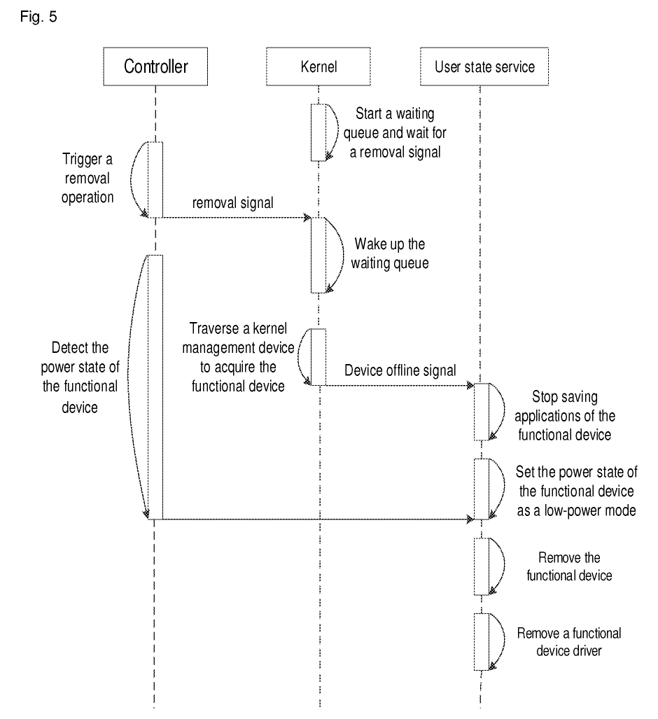

The timing diagram of functional device removal is shown in FIG. 5. A waiting queue of the kernel module of motherboard 1 is responsible for monitoring device removal signals transmitted by the controller. When the monitoring switching module of the controller receives a link request from an administrator or the motherboard, the monitoring switching module transmits the device removal signal to motherboard 1, triggering a waiting queue of the kernel module. This signal can be implemented in an interrupt mode, wherein the waiting queue of the kernel module receives and responds to the interrupt, or in a status signal mode, where the waiting queue of the kernel module needs to detect link status changes in real time. After receiving the device removal signal, the kernel module traverses all functional devices, finds and prepares to remove the functional device among all the functional devices, and passes relevant information to the device unloading module in the user state. The device unloading module first suspends or saves the applications or services using the functional device, such as the display manager GDM service using the VGA device in the Linux system, to prevent damage to these applications or services caused by device removal. Next, the device unloading module sets the power state of the functional device to a low-power mode, turning off most functions of the functional device and retaining only partial functions used for waking up and initializing the functional device. Subsequently, the device unloading module requests the operating system to remove the functional device from the maintained managed device set. The operating system no longer manages the functional device and removes the driver of the functional device in the system to prevent misuse of the functional device. The controller side detects the power state of the device. When the device unloading module in the user state sets the power state of the device to the low-power mode, the controller can determine that the user state is no longer using the functional device and can apply to a multiplexer to disconnect the link between the functional device and motherboard 1, completing the device removal operation.

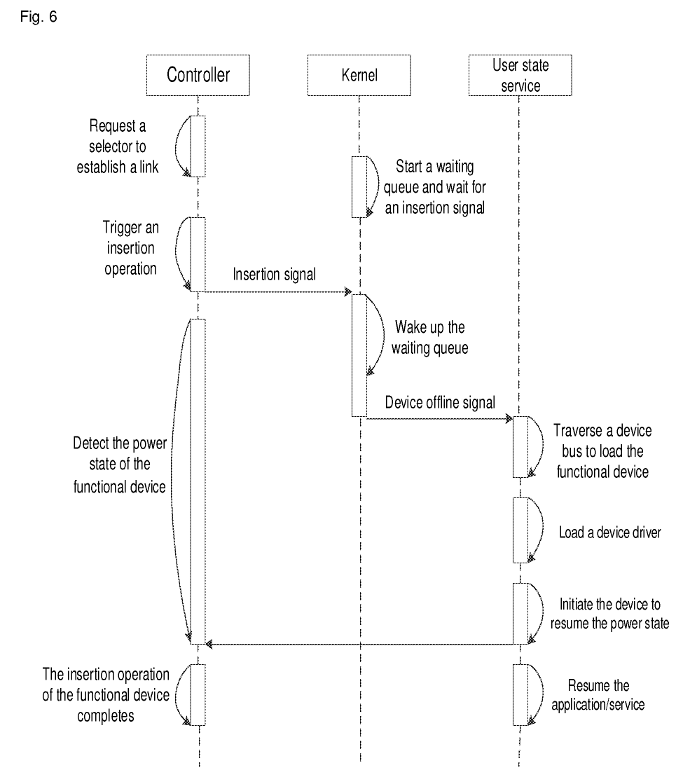

The timing diagram of functional device insertion is shown in FIG. 6. The controller applies to a multiplexer to establish a device link between the functional device and motherboard 2 and notifies a new motherboard to use the functional device. The kernel module of the new motherboard similarly monitors a device insertion signal through a waiting queue. When receiving the device insertion signal, the kernel module is woken up and starts executing an insertion operation. The device probing module in the user state first probes a device bus, adds a new functional device to the device set, and establishes management of an inserted functional device. Next, the driver of the functional device is loaded, enabling users of the new motherboard to use the functional device. Since the functional device has entered the low-power mode before removal, a power of the functional device needs to be set before the new motherboard needs to use the functional device, enabling all of the functions thereof to run. When detecting that motherboard 2 has the applications or services previously suspended due to device removal, the device probing module needs to wake up and resume these applications, enabling them to continue running normally.

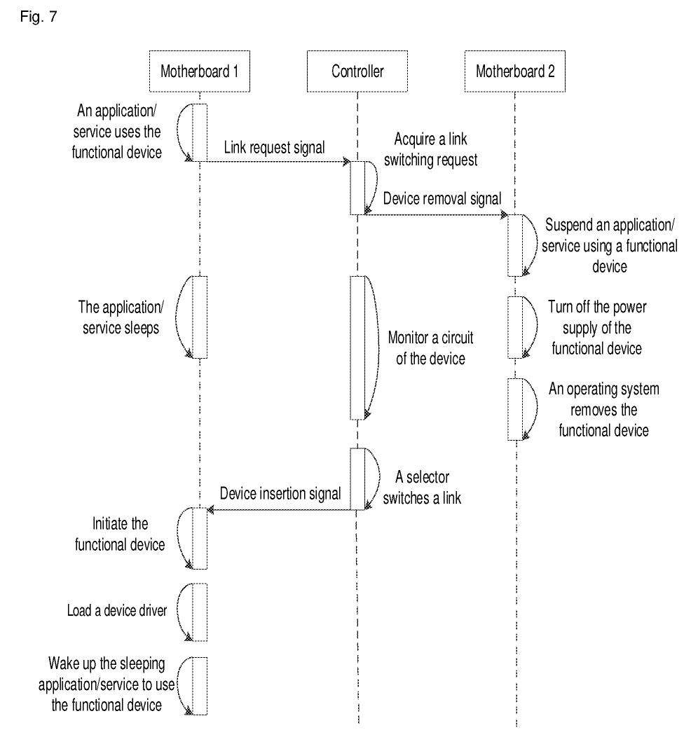

The timing diagram of the motherboard application requesting to switch the device link is shown in FIG. 7. An application or service of the motherboard needs to use the functional device, and there is no link with the functional device. The motherboard initiates a link switching request to the controller through the link request module, causing the controller to trigger a monitoring switching process to establish a link between the functional device and the current motherboard. After issuing the link switching request, the motherboard application or service enters a waiting sleep state and wakes up the sleeping service after device insertion. After receiving the link switching request initiated by the link request module, the controller transmits a device removal request to the original motherboard and starts executing a device removal process. The controller detects a power state of the functional device in real time. When the device power state is set to a low-power mode, it indicates that the original motherboard has removed management of the functional device. The controller disconnects the device link with the original motherboard and establishes the device link with the new motherboard through the routing control module. The new motherboard completes a device insertion operation and wakes up the waiting application to normally use the functional device.

The embodiments of the present disclosure provide a method for managing motherboards. The method is described in detail in conjunction with the execution flow of the method for managing motherboards.

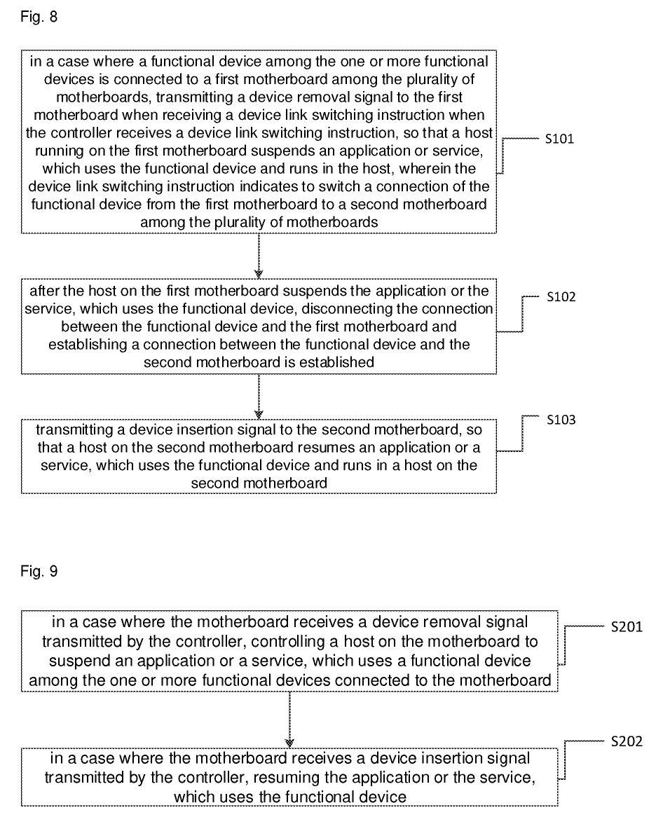

Referring to FIG. 8, a flowchart of a method for managing motherboards according to an exemplary embodiment is shown in FIG. 8, the controller is respectively connected to a plurality of motherboards and one or more functional devices, including the following steps.

At S101, in a case where a functional device among the one or more functional devices is connected to a first motherboard among the plurality of motherboards, transmitting a device removal signal to the first motherboard when receiving a device link switching instruction when the controller receives a device link switching instruction, so that a host running on the first motherboard suspends an application or service, which uses the functional device and runs in the host, wherein the device link switching instruction indicates to switch a connection of the functional device from the first motherboard to a second motherboard among the plurality of motherboards.

The execution subject of this embodiment is a controller, and the controller provides the functional device for different motherboards at different times. In this embodiment, the controller is responsible for managing connections between the one or more functional devices and the plurality of motherboards. When a functional device of the one or more functional devices is currently connected to a first motherboard among the plurality of motherboards and the controller receives the device link switching instruction, the controller transmits the device removal signal to the first motherboard. The purpose of this signal is to notify the host running on the first motherboard that it needs to suspend all of the applications or services currently using the functional device. The device link switching instruction explicitly indicates that the functional device needs to be disconnected from the first motherboard and reconnected to a second motherboard among the plurality of motherboards. This process ensures that the corresponding applications or services on the host running on the first motherboard are properly handled before the functional device performs link switching, preventing data loss or service interruption.

At S102, after the host on the first motherboard suspends the application or the service, which uses the functional device, disconnecting the connection between the functional device and the first motherboard and establishing a connection between the functional device and the second motherboard is established.

After the host running on the first motherboard successfully suspends the application or service using the functional device, the controller executes the next step, i.e., disconnecting the connection between the functional device and the first motherboard. This is realized through the routing control module inside the controller, and the routing control module is responsible for managing physical links between the functional device and the motherboard. After disconnecting the connection with the first motherboard, the controller immediately establishes a connection between the functional device and the second motherboard. This step is a key action in a functional device link switching process, ensuring that the functional device can smoothly transition from the old connection to the new connection, preparing for the second motherboard to use the functional device.

As a feasible implementation, the power state of the functional device is set to a low-power state after the host running on the first motherboard suspends the application or service, which uses the functional device; correspondingly, the operation of disconnecting the connection between the functional device and the first motherboard and establishing the connection between the functional device and the second motherboard after the host running on the first motherboard suspends the application or the service, which uses the functional device includes: disconnecting the connection between the functional device and the first motherboard and establishing the connection between the functional device and the second motherboard when detecting that the power state of the functional device is the low-power state.

In specific implementation, after the host running on the first motherboard completes suspending the application or service, which uses the functional device, it not only suspends these applications or services but also adjusts the power state of the functional device to a low-power mode. This step is to reduce energy consumption of the functional device during switching and ensure minimal power consumption of the device in a non-active state. The low-power state usually means the functional device maintains only basic operations to facilitate quick waking when needed. Once the functional device enters the low-power state, the controller detects this change and executes link switching operations accordingly. Specifically, the controller disconnects the connection between the functional device and the first motherboard and simultaneously establishes the connection between the functional device and the second motherboard. This process ensures that the functional device can safely and efficiently switch from the first motherboard to the second motherboard while minimizing service interruption time potentially caused by device switching.

As a feasible implementation, the operation of disconnecting the connection between the functional device and the first motherboard and establishing the connection between the functional device and the second motherboard includes: controlling a multiplexer to disconnect the connection with the first motherboard and establish the connection with the second motherboard; where the functional devices of different types are connected to different multiplexer controllers.

In specific implementation, the multiplexer is configured to switch connections of the functional devices between different motherboards. When the functional device needs to be switched from the first motherboard to the second motherboard, the controller instructs the corresponding multiplexer to disconnect the connection with the first motherboard and establish the connection with the second motherboard. This control method allows precise management of connections between the functional device and the motherboard, ensuring that the functional device is connected to only one motherboard at any given time. In addition, the functional devices of different types may be connected to different multiplexer controllers, allowing more effective management and optimization of resource usage.

At S103, transmitting a device insertion signal to the second motherboard, so that a host on the second motherboard resumes an application or a service, which uses the functional device and runs in a host on the second motherboard.

In specific implementation, after the connection between the functional device and the second motherboard is established, the controller transmits the device insertion signal to the second motherboard. The function of this signal is to notify the host running on the second motherboard that the functional device is now ready and can be used. After receiving the device insertion signal, the host running on the second motherboard resumes all of the applications or services suspended due to link switching, enabling them to restart using the functional device. This step ensures seamless integration of the functional device on the second motherboard and continuity of the applications, thereby minimizing service interruption time caused by device link switching and improving reliability and user experience of the entire system.

Based on the above embodiment, as a preferred implementation, the method further includes: in a case where the functional device is connected to the first motherboard, executing the step of transmitting a device removal signal to the first motherboard when receiving a link request signal of the second motherboard.

In specific implementation, when the host running on the second motherboard needs to use the functional device and the controller receives its link request signal, the controller transmits the device removal signal to the first motherboard. This step is to prepare for switching the functional device from the first motherboard to the second motherboard. In this way, the controller can more flexibly respond to demands of different motherboards and optimize usage of the functional devices. After the first motherboard receives the device removal signal, the host running on the first motherboard suspends the applications or services using the functional device and may set the functional device to a low-power state. Subsequently, the controller disconnects the connection between the functional device and the first motherboard and establishes the connection with the second motherboard, enabling the host running on the second motherboard to start using the functional device. This implementation improves flexibility and efficiency of the system, ensuring that the functional devices can be dynamically allocated according to actual demands of the hosts.

The embodiments of the present disclosure disclose a method for managing motherboards, specifically as follows.

Referring to FIG. 9, a flowchart of another method for managing motherboards according to an exemplary embodiment is shown in FIG. 9, the method applied to a motherboard among a plurality of motherboards in a motherboard management system, wherein a controller in the motherboard management system is respectively connected to the plurality of motherboards and one or more functional devices, the method including the following steps.

At S201, in a case where the motherboard receives a device removal signal transmitted by the controller, controlling a host on the motherboard to suspend an application or a service, which uses a functional device among the one or more functional devices connected to the motherboard.

The execution subject of this embodiment is a motherboard among the plurality of motherboards. In specific implementation, the motherboard responds to the device removal signal from the controller and suspends all of the applications or services currently, which uses the functional device.

As a feasible implementation, the operation of controlling a host on the motherboard to suspend the application or the service, which uses the functional device includes: suspending or saving the application or the service, which uses the functional device, removing the functional device from a maintained managed device set, and unloading a driver of the functional device.

In specific implementation, when the motherboard receives the device removal signal transmitted by the controller, a host running on the motherboard suspends or saves all of the applications or services currently using the functional device to prevent data loss or service interruption. Next, the functional device is removed from its maintained managed device set, meaning the host no longer regards the functional device as an active device. Finally, the driver of the functional device is unloaded to ensure no driver conflicts or system errors occur during device removal. Through these steps, the host prepares for physical removal of the functional device while guaranteeing system stability and data security.

At S202, in a case where the motherboard receives a device insertion signal transmitted by the controller, resuming the application or the service, which uses the functional device.

In specific implementation, the motherboard responds to the device insertion signal transmitted by the controller, and the host running on the motherboard resumes use of the applications and services of the functional device.

As a feasible implementation, the operation of resuming the application or service, which uses the functional device includes: adding the functional device to a maintained managed device set, loading a driver of the functional device, and resuming the application or service using the functional device.

In specific implementation, the host running on the motherboard adds the functional device to its maintained managed device set, so the host identifies and manages the functional device. Then, the driver of the functional device is loaded, and the applications or services previously suspended due to device removal are resumed, enabling them to continue using the functional device. This process ensures rapid integration of the functional device on the new host and continuity of the applications, minimizing service interruption time.

As a feasible implementation, after suspending or saving the application or service, which uses the functional device, the operation further includes: setting a power state of the functional device to a low-power state; correspondingly, after loading the driver of the functional device, the operation further includes: setting the power state of the functional device to a working state.

In specific implementation, after suspending or saving the application or service, which uses the functional device, the host running on the motherboard sets the power state of the functional device to a low-power mode to reduce energy consumption and prepare for safe removal of the functional device. Correspondingly, after the new host loads the driver of the functional device, it sets the power state of the functional device back to the working state, enabling the functional device to operate normally and provide services. This power state management not only helps save energy but also ensures safety and reliability of the functional device during switching.

As a preferred implementation, the operation further includes: determining whether a connection exists between the functional device and a motherboard where the device application module is located before the application or the service uses the functional device; in a case where a connection does not exist between the functional device and the motherboard where the device application module is located, transmitting a link request signal to the controller, so that the motherboard establishes a connection between the functional module and the motherboard where the device application module is located.

Before attempting to use the functional device, the host checks whether a connection has been established between the device and its own motherboard. If a connection has been established, the application is executed normally. If no connection is found, the motherboard actively sends the link request signal to the controller, requesting establishment of a connection between the functional device and the motherboard. This mechanism enables the motherboard to dynamically request and establish connections according to actual demands, improving flexibility and response speed of the system.

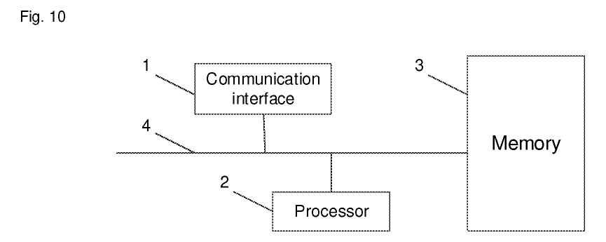

The embodiments of the present disclosure further provide an electronic device. FIG. 10 is a structural diagram of an electronic device according to an exemplary embodiment. As shown in FIG. 10, the electronic device includes a communication interface 1, a processor 2, a memory 3, and a bus system 4.

The communication interface 1 is capable of exchanging information with other devices such as network devices.

The processor 2 is connected to the communication interface 1 to realize information exchange with other devices, configured to execute steps of the motherboard management method provided by one or more of the above technical solutions when running a computer program. The computer program is stored on the memory 3.

Of course, in practical applications, various components in the electronic device are coupled together through a bus system 4. It can be understood that the bus system 4 is configured to realize connection communication between these components. Besides a data bus, the bus system 4 further includes a power bus, a control bus, and a status signal bus. However, all of the buses are labeled as the bus system 4 in FIG. 10 for clarity.

The memory 3 in the embodiment of the present disclosure is configured to store various types of data to support operations of the electronic device. Examples of these data include: any computer program used for operation on the electronic device.

It can be understood that the memory 3 may be volatile memory or non-volatile memory, and may include both volatile and non-volatile memory. Non-volatile memory may be Read Only Memory (ROM), Programmable Read-Only Memory (PROM), Erasable Programmable Read-Only Memory (EPROM), Electrically Erasable Programmable Read-Only Memory (EEPROM), ferromagnetic random access memory (FRAM), Flash Memory, magnetic surface memory, optical disk, or Compact Disc Read-Only Memory (CD-ROM); magnetic surface memory may be disk storage or tape storage. Volatile memory may be Random Access Memory (RAM), serving as an external high-speed cache. By way of exemplary but not limiting illustration, many forms of RAM are available, such as Static Random Access Memory (SRAM), Synchronous Static Random Access Memory (SSRAM), Dynamic Random Access Memory (DRAM), Synchronous Dynamic Random Access Memory (SDRAM), Double Data Rate Synchronous Dynamic Random Access Memory (DDRSDRAM), Enhanced Synchronous Dynamic Random Access Memory (ESDRAM), SyncLink Dynamic Random Access Memory (SLDRAM), and Direct Rambus Random Access Memory (DRRAM). The memory 3 described in the embodiment of the present disclosure is intended to include but not limited to these and any other suitable types of memory.

The methods disclosed in the above embodiments of the present disclosure may be applied to the processor 2 or implemented by the processor 2. The processor 2 may be an integrated circuit chip with signal processing capability. In the implementation process, steps of the above methods may be completed by integrated logic circuits of hardware in the processor 2 or instructions in software form. The above processor 2 may be a general-purpose processor, a DSP, or other programmable logic devices, discrete gate or transistor logic devices, discrete hardware components, etc. The processor 2 may implement or execute various methods, steps, and logical block diagrams disclosed in the embodiments of the present disclosure. The general-purpose processor may be a microprocessor or any conventional processor, etc. Combined with the steps of the methods disclosed in the embodiments of the present disclosure, they can be directly embodied as being executed by a hardware decoding processor, or executed by a combination of hardware and software modules in the decoding processor. Software modules may be located in a storage medium, and the storage medium is located in the memory 3. The processor 2 reads programs in the memory 3 and completes the steps of the above methods in combination with its hardware.

The processor 2, when executing programs, implements corresponding processes in the various methods of the embodiments of the present disclosure. Details are not repeated here for brevity.

The embodiments of the present disclosure further provide a computer-readable storage medium. A computer program is stored in the computer-readable storage medium, where the computer program is configured to, when running, execute the steps in any one of the above method for managing motherboards embodiments.

In an exemplary embodiment, the above computer-readable storage medium may include, but is not limited to: a USB flash drive, Read-Only Memory (ROM), Random Access Memory (RAM), a portable hard disk, a magnetic disk, or an optical disc, and various other media capable of storing computer programs.

Embodiments of the present disclosure further provide a computer program product. The above computer program product includes a computer program. The computer program, when executed by the processor 2, implements the steps in any one of the above method for managing motherboards embodiments.

Embodiments of the present disclosure further provide another computer program product including a non-volatile computer-readable storage medium. The non-volatile computer-readable storage medium stores a computer program, and the computer program, when executed by the processor 2, implements the steps of any one of the above method for managing motherboards embodiments.

Professionals may further realize that the units and algorithm steps of the examples described in conjunction with the embodiments disclosed herein can be implemented by electronic hardware, computer software, or a combination of both. To clearly illustrate the interchangeability of hardware and software, the composition and steps of the various examples have been generally described above according to function. Whether these functions are executed by hardware or software depends on specific application and design constraints of the technical solution. Professional technicians may use different methods to implement the described functions for each of specific applications, but such implementation should not be considered as exceeding the scope of the present disclosure.

The motherboard management system, method, apparatus, device, medium, and product provided by the present disclosure have been introduced in detail above. Specific examples are applied herein to elaborate the principles and implementations of the present disclosure. The descriptions of the above embodiments are only used for helping understand the method and core idea of the present disclosure. It should be pointed out that for those of ordinary skill in the art, without departing from the principle of the present disclosure, several improvements and modifications may further be made to the present disclosure, and such improvements and modifications shall also fall within the protection scope of the present disclosure.

1. A system for managing motherboards, the system comprising a controller and a plurality of motherboards, wherein the controller is respectively connected to the plurality of motherboards and one or more functional devices;
the controller is configured to: in a case where a functional device among the one or more functional devices is connected to a first motherboard among the plurality of motherboards, receive a device link switching instruction and transmit a device removal signal to the first motherboard, wherein the device link switching instruction indicates to switch a connection of the functional device from the first motherboard to a second motherboard among the plurality of motherboards;
the first motherboard is configured to: in a case where the first motherboard receives the device removal signal, control a host on the first motherboard to suspend an application or a service, which uses the functional device and runs in the host;
the controller is further configured to: after the host on the first motherboard suspends the application or the service, which uses the functional device, disconnect the connection between the functional device and the first motherboard, establish a connection between the functional device and the second motherboard, and transmit a device insertion signal to the second motherboard; and
the second motherboard is configured to: in a case where the second motherboard receives the device insertion signal, resume an application or a service, which uses the functional device and runs in a host on the second motherboard.

2. The system for managing motherboards according to claim 1, wherein the controller is connected to a plurality of multiplexers, each multiplexer among the plurality of multiplexers is respectively connected to the plurality of motherboards and a corresponding type functional device among the one or more functional devices, and each multiplexer among the plurality of multiplexers is configured to control establishment or disconnection of a connection between the corresponding type functional device and the plurality of motherboards.

3. The system for managing motherboards according to claim 2, wherein the controller comprises a management module, a monitoring switching module, and a routing control module;
the management module is configured to: receive the device link switching instruction and transmit the device link switching instruction to the monitoring switching module;
the monitoring switching module is configured to: transmit the device removal signal to the first motherboard in a case where the monitoring switching module receives the device link switching instruction, and transmit a device link switching request to the routing control module after the host on the first motherboard suspends the application or the service, which uses the corresponding type functional device;
the routing control module is configured to: in a case where the routing control module receives the device link switching request, control the multiplexer to disconnect a connection with the first motherboard and control the multiplexer to establish a connection with the second motherboard; and
the monitoring switching module is further configured to: transmit the device insertion signal to the second motherboard after the multiplexer establishes the connection with the second motherboard.

4. The system for managing motherboards according to claim 2, wherein the controller further comprises a log recording module and an exception handling module;
the log recording module is configured to: record an operation log during a device link switching process, wherein the operation log includes any one or any combination of a reception time of the device removal signal, a transmission time of the device insertion signal, and a switching action of the multiplexer; and
the exception handling module is configured to: in a case where the exception handling module detects an exception condition during the device link switching process, execute an exception handling strategy corresponding to the exception condition.

5. The system for managing motherboards according to claim 1, wherein an operating system of a host running on a motherboard among the plurality of motherboards comprises a kernel state and a user state, the kernel state comprises a removal signal monitoring module and an insertion signal monitoring module, and the user state comprises a device unloading module and a device probing module;
the removal signal monitoring module is configured to: monitor the device removal signal, and in a case where the removal signal monitoring module monitors the device removal signal, transmit the device removal signal to the device unloading module;
the device unloading module is configured to: in a case where the device unloading module receives the device removal signal, suspend an application or a service, which uses the functional device and runs in the host on the motherboard among the plurality of motherboards;
the insertion signal monitoring module is configured to: monitor the device insertion signal, and in a case where the insertion signal monitoring module detects the device insertion signal, transmit the device insertion signal to the device probing module; and
the device probing module is configured to: in a case where the device probing module receives the device insertion signal, resume the application or the service, which uses the functional device and runs in the host on the motherboard among the plurality of motherboards.

6. The system for managing motherboards according to claim 5, wherein the device unloading module is specifically configured to: in a case where the device unloading module receives the device removal signal, suspend or save the application or the service, which uses the functional device and runs in the host on the motherboard among the plurality of motherboards, remove the functional device from a maintained managed device set, and unload a driver of the functional device;
the device probing module is specifically configured to: add the functional device to the maintained managed device set, load the driver of the functional device, and resume the application or the service, which uses the functional device and runs in the host on the motherboard among the plurality of motherboards.

7. The system for managing motherboards according to claim 6, wherein the device unloading module is further configured to: after the device unloading module suspends or saves the application or the service, which uses the functional device and runs in the host on the motherboard among the plurality of motherboards, set a power state of the functional device to a low-power state;
the device probing module is further configured to: after the device probing module loads the driver of the functional device, set the power state of the functional device to a working state.

8. The system for managing motherboards according to claim 7, wherein the controller is specifically configured to: in a case where the controller detects that the power state of the functional device is the low-power state, disconnect the connection between the functional device and the first motherboard, and establish the connection between the functional device and the second motherboard.

9. The system for managing motherboards according to claim 5, wherein the kernel state further comprises a link request module, and the user state further comprises a device application module;
the device application module is configured to: determine whether a connection exists between the functional device and a motherboard where the device application module is located before the application or the service uses the functional device, and in a case where a connection does not exist between the functional device and the motherboard where the device application module is located, transmit a link request signal to the link request module;
the link request module is configured to: transmit the link request signal to the controller in a case where the link request module receives the link request signal; and
the controller is configured to: trigger device link switching in a case where the controller receives the link request signal.

10. The system for managing motherboards according to claim 1, wherein the functional device comprises any one or any combination of a storage device, a network device, and a graphics processing device;
the controller is further configured to: generate an instruction for adjusting a resource allocation strategy of the functional device according to a type and a current connection state of the functional device;
the motherboard further comprises a resource management module, which configured to allocate and adjust resources of the functional device according to the instruction of the controller.

11. A method for managing motherboards, the method applied to a controller, wherein the controller is respectively connected to a plurality of motherboards and one or more functional devices, the method comprising:
in a case where a functional device among the one or more functional devices is connected to a first motherboard among the plurality of motherboards, transmitting a device removal signal to the first motherboard when the controller receives a device link switching instruction, so that a host on the first motherboard suspends an application or a service, which uses the functional device and runs in the host, wherein the device link switching instruction indicates to switch a connection of the functional device from the first motherboard to a second motherboard among the plurality of motherboards;
after the host on the first motherboard suspends the application or the service, which uses the functional device, disconnecting the connection between the functional device and the first motherboard and establishing a connection between the functional device and the second motherboard; and
transmitting a device insertion signal to the second motherboard, so that a host on the second motherboard resumes an application or a service, which uses the functional device and runs in a host on the second motherboard.

12. The method for managing motherboards according to claim 11, wherein the disconnecting the connection between the functional device and the first motherboard and establishing the connection between the functional device and the second motherboard comprises:
controlling a multiplexer to disconnect the connection with the first motherboard and establish the connection with the second motherboard; wherein the functional devices of different types are connected to different multiplexer controllers.

13. The method for managing motherboards according to claim 11, where the method further comprises:
in a case where the functional device is connected to the first motherboard, when the controller receives a link request signal of the second motherboard, executing the step of transmitting the device removal signal to the first motherboard.

14. A method for managing motherboards, the method applied to a motherboard among a plurality of motherboards in a motherboard management system, wherein a controller in the motherboard management system is respectively connected to the plurality of motherboards and one or more functional devices, the method comprising:
in a case where the motherboard receives a device removal signal transmitted by the controller, controlling a host on the motherboard to suspend an application or a service, which uses a functional device among the one or more functional devices connected to the motherboard; and
in a case where the motherboard receives a device insertion signal transmitted by the controller, resuming the application or the service, which uses the functional device.

15. The method for managing motherboards according to claim 14, wherein the controlling a host on the motherboard to suspend the application or the service, which uses the functional device comprises:
suspending or saving the application or the service, which uses the functional device, removing the functional device from a maintained managed device set, and unloading a driver of the functional device.

16. The method for managing motherboards according to claim 14, wherein the resuming the application or the service, which uses the functional device comprises:
adding the functional device to a maintained managed device set, loading the driver of the functional device, and resuming the application or service using the functional device.

17. The method for managing motherboards according to claim 14, wherein the method further comprises:
determining whether a connection exists between the functional device and a motherboard where the device application module is located before the application or the service uses the functional device;
in a case where a connection does not exist between the functional device and the motherboard where the device application module is located, transmitting a link request signal to the controller, so that the motherboard establishes a connection between the functional module and the motherboard where the device application module is located.

18. An electronic device, comprising:
a memory, configured to store a computer program; and
a processor, configured to execute the steps performed by the method for managing motherboards according to claim 11 when executing the computer program.

19. A computer-readable storage medium, wherein a computer program is stored on the computer-readable storage medium, and the computer program, when executed, implements the steps performed by the method for managing motherboards according to claim 11.

20. A computer program product, comprising a computer program, wherein the computer program, when executed, implements the steps performed by the method for managing motherboards according to claim 11.
